(19) United States
(12) Patent Application Publication
(10) Pub. No.: US 2010/0277175 A1
(43) Pub. Date: Nov. 4, 2010

(54) TUNABLE AND/OR DETUNABLE MR RECEIVE COIL ARRANGEMENTS

(75) Inventor: Steffen Weiss, Hamburg (DE)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V., EINDHOVEN (NL)

(21) Appl. No.: 12/377,607

(22) PCT Filed: Aug. 10, 2007
(86) PCT No.: PCT/IB07/53177

§ 371 Date: Feb. 16, 2009

(30) Foreign Application Priority Data
Aug. 15, 2006 (EP) 06118913.0

(51) Int. Cl. G01R 33/44

(52) U.S. Cl. 324/318

(57) ABSTRACT

MR receive (or reception) coil arrangements are disclosed which comprise at least one MR receive coil or coil element or coil system (9) which can be tuned and/or detuned in relation to an MR frequency, and which further comprise a transmission line (7) for electrically connecting the MR receive coil or coil element or coil system (9) with an MR receiver (10). Especially such MR receive coil arrangements are disclosed which are not provided for being stationarily (or permanently) installed or built in an examination zone of an MR imaging or examination system or apparatus (MRI system), like a whole-body coil system of such an MRI system, but which are mobile, like e.g. interventional or invasive devices, like catheters, or surface coils, e.g. in the form of (especially flexible) pads which are positioned on a surface of an examination object for examining a region of interest, or volume coils like birdcage coils for enclosing and examining a volume of interest. Finally, an MR imaging or examination system (MRI system) comprising such an MR receive coil arrangement is disclosed.

### FIELD OF THE INVENTION

The invention relates to MR receive (or reception) coil arrangements which comprise at least one MR receive coil or coil element or coil system which can be tuned and/or detuned especially in relation to an MR frequency, and which further comprise a transmission line for electrically connecting the MR receive coil or coil element or coil system with an MR receiver. The invention especially relates to such MR receive coil arrangements which are not provided for being stationarily (or permanently) installed or built in an examination zone of an MR imaging or examination system or apparatus (MRI system), like a whole-body coil system of such an MRI system, but which are mobile, like e.g. interventional or invasive devices, like catheters, or surface coils, e.g. in the form of (especially flexible) pads which are positioned on a surface of an examination object for examining a region of interest, or volume coils like birdcage coils for enclosing and examining a volume of interest. Finally, the invention relates to an MR imaging or examination system (MRI system) comprising such an MR receive coil arrangement.

### BACKGROUND OF THE INVENTION

An MR imaging system may be used in the examination and/or treatment of patients. The nuclear spins of the body tissue to be examined are aligned by a steady main magnetic field (B₀ field) and are excited by RF pulses (B₁ field). Due to the excitation, the nuclear spins precede around a direction of the main magnetic field (B₀ field) at a flip angle. The nuclear spins are further exposed to gradient magnetic fields for the purpose of localization. After excitation, the nuclear spins relax, thereby aligning with the main magnetic field (B₀ field). The emitted relaxation signals, hereinafter referred to as MR signals, are received by a suitable MR receive coil arrangement and an MR receiver and are processed by an MR signal processing system, in order to form a one-, two- or three-dimensional image of the examination object from the received MR signals in a known manner.

Essentially two types of MR examination or imaging systems (MRI system) can be distinguished. The first one is the so-called open MR system (vertical system) in which a patient is introduced into an examination zone, which is located between the ends of a C-arm. The patient is accessible during the examination or treatment from practically all sides. The second one is an MR system which comprises a horizontally extending tubular (cylindrical) examination space (axial system) into which a patient is introduced.

RF/MR coils or coil systems are provided for the transmission of the RF pulses and/or the reception of the relaxation (MR) signals. In addition to the RF/MR coil systems which are permanently built into the MR imaging apparatus like whole-body coils for imaging substantially the whole-body of a patient, use may also be made of the above mentioned mobile MR receive coil arrangements like MR surface coils which can be flexibly arranged, for example, as a sleeve or pad around or in a specific region of the object to be examined.

Furthermore, mobile MR receive coil arrangements are provided in the form of interventional devices like e.g. a catheter or another invasive device, which is introduced into the patient, for example in order to take a sample of tissue during the MR imaging. Such an interventional device comprises at least one MR receive coil (or coil element), such as an oscillator or the like. The MR receive coil may be positioned at an area of a tip of the device (especially a catheter) for the purpose of localization in an image formed, i.e. for catheter tracking, or for the purpose of imaging of the tissue in a local area around the invasive device. Such invasive devices comprising an MR receive coil (or coil element) may be employed for imaging with a high signal-to-noise ratio (SNR), thus enabling very robust and fast active catheter tracking and/or intravascular imaging with a very high SNR in a local area around the MR receive coil.

Such a mobile MR receive coil is generally made resonant during the phase of reception of MR relaxation signals. However, during the phase of excitation by transmitting RF pulses by means of the whole-body RF coil systems, the magnetic field will be inhomogeneous in an area near the MR receive coil, if the MR receive coil is resonant at or near the frequency of the RF pulses. This is due to an inhomogeneous spatial distribution of the flip angle of the nuclear spins of the tissue in a sensitivity range of the MR receive coil. Such an undefined flip angle gives rise to large scale image artifacts and inferior signal to noise ratio (SNR). Therefore, during the transmission of the RF pulses, the (mobile) MR receive coils are to be detuned temporarily in order to preserve the homogeneity of the RF excitation field of the whole-body RF coil system.

US 2004/0124838 discloses a wireless detuning of a resonant circuit of a device in an MR imaging system which system detects and emits RF signals within a first range when acquiring data, wherein the device further comprises an opto-electronic component electrically communicating with the resonant circuit, and a means for controlling the opto-electronic component to operate in a plurality of modes, wherein the electrical components of the resonant circuit are not sensitive to the RF signals within the first range when the opto-electronic component is operating in one of the modes.

### SUMMARY OF THE INVENTION

It has revealed that, on the one hand, a wireless detuning of a resonant circuit within a mobile MR receive coil arrangement as defined above is not sufficiently reliable under all operating conditions. On the other hand, a disadvantage of a tuning/detuning via a line or cable connection is the fact that the line or cable connection may be heated by the transmitted RF pulses due to standing waves on the line because the line usually has to be guided into and through the RF excitation field, especially within the examination zone of the MRI system. Such a heating may possible result in a damage of certain components of the MR receive coil arrangement, and furthermore a patient might be hurt by the heated line.

One object underlying the invention is to provide a tunable and/or detunable MR receive coil arrangement as defined in the introductory part above, which does not cause the above disadvantages or risks of a wireless connection or of a line connection.

Furthermore, an object underlying the invention is to provide an MR imaging or examination system (MRI system) which can be operated during an RF puls transmission mode with an MR receive coil arrangement within the examination zone without substantially causing inhomogeneous RF field distribution in the local sensitivity range or area of the MR receive coil arrangement, especially of an MR receive coil or coil element or coil system of such an MR receive coil arrangement.

The object is solved according to claim 1 by an MR receive coil arrangement which comprises at least one MR receive coil or coil element or coil system which can be tuned and/or detuned especially in relation to an MR frequency, and which arrangement further comprises a transmission line for electrically connecting the MR receive coil or coil element or coil system with an MR receiver, wherein the transmission line is an RF safe transmission line and wherein a tuning and/or detuning circuit is provided which can be controlled for tuning and/or detuning, respectively, the MR receive coil or coil element or coil system by means of an RF control signal having a frequency such that it can be transmitted over the transmission line to the tuning and/or detuning circuit.

Generally, reference is often made to a tuning circuit. Tuning is to be understood as tuning the receive coil at a certain frequency. Thus, tuning may be tuning at the MR frequency for receiving a RF MR (relaxation) signal. However, tuning may as well be tuning at another frequency in order not to receive a RF signal at the MR frequency, e.g. during RF pulse transmission, which is also known in the art as detuning. Therefore, tuning is to be understood as comprising tuning and detuning.

The solution according to claim 1 has the advantage that a cable connection is provided which is more reliable for controlling the tuning and/or detuning of the MR receiver coil than a wireless connection. By providing an RF safe transmission line, problems and risks in connection with an RF heating of the line running within the examination zone are avoided, wherein in order to enable a transmission of the control signal, the control signal is an RF control signal with a frequency preferably within the bandwidth of the RF safe transmission line.

An RF safe transmission line (STL) is known in the prior art and is for example a segmented transmission line, in which the line segments are connected to each other via inductive couplings, for example by means of transformers, so that such RF safe transmission lines cannot be used for transmitting DC signals.

The dependent claims disclose advantageous and exemplary embodiments of the invention.

The embodiment according to claim 2 has the advantage that only one (common) transmission line is needed for transmitting received MR signals from the MR receive coil to an MR receiver and for transmitting the RF control signal to the MR receive coil.

In case of the common transmission line according to claim 2, a two-way branch according to claim 3 has the advantage, that interferences or disturbances between both signals are avoided. This branch can be realized by appropriate filters at the input of an MR receiver and at the output of an RF transmitter for generating the RF control signal, or by a circulator or by other appropriate devices.

The embodiment according to claim 4 has the advantage, that a tuning and/or detuning circuit which can be controlled by means of (selectable) amplitudes of an RF control signal can be realized in a comparatively simple manner.

The embodiment according to claim 5 allows in combination with the embodiment according to claim 4 a very simple tuning and/or detuning of the MR receive coil.

The dependent claims 6 to 8 are directed on advantageous tuning and/or detuning circuits, wherein the embodiment according to claim 8 has the additional advantage, that it can be used for tuning flexible or expandable MR coils during MR signal reception as well.

The dependent claim 9 is directed on preferred embodiments of the MR receive coil arrangement, wherein claim 10 is directed on an MR imaging system comprising an MR receive coil arrangement according to the invention.

It will be appreciated that features of the invention are susceptible to being combined in any combination without departing from the scope of the invention as defined by the accompanying claims.

Further details, features and advantages of the invention will become apparent from the following description of preferred and exemplary embodiments of the invention which are given with reference to the drawings.

### BRIEF DESCRIPTION OF THE DRAWINGS

FIG. 1 schematically illustrates an MR imaging or examination system;

FIG. 2 schematically illustrates an interventional device;

FIG. 3 shows a graph indicating a transfer characteristic of a transformer based transfer cable or transmission line;

FIG. 4 schematically illustrates a first embodiment of an AC controlled tuning and/or detuning circuit according to the invention;

FIG. 5 schematically illustrates a second embodiment of an AC controlled tuning and/or detuning circuit according to the invention; and

FIG. 6 schematically illustrates a third embodiment of an AC controlled tuning and/or detuning circuit according to the invention.

### DETAILED DESCRIPTION OF EMBODIMENTS

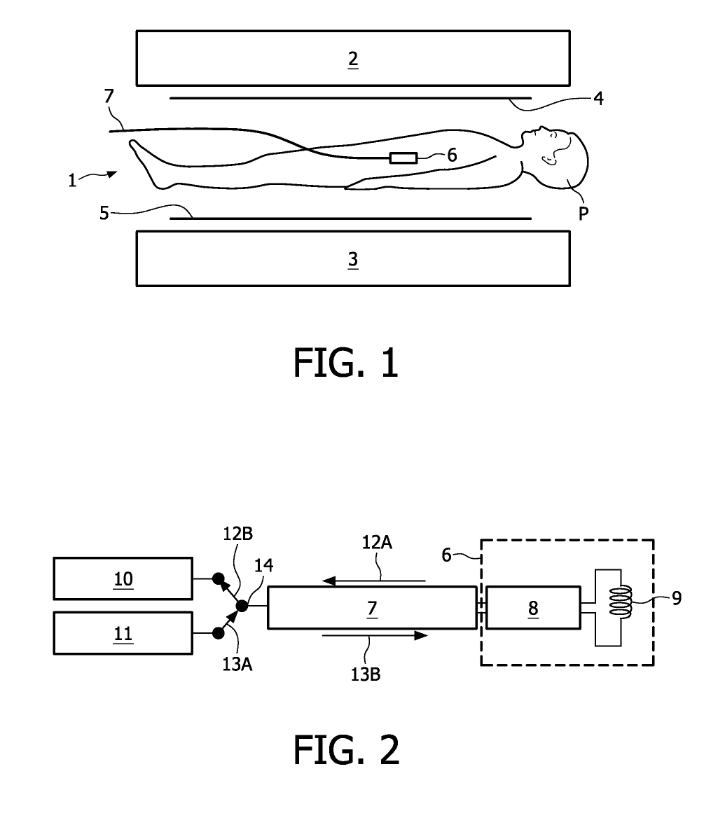

In the drawings like reference numerals refer to like components. FIG. 1 shows an MR imaging system defining an examination zone 1, in which a patient P has been positioned. The MR imaging system comprises a magnet 2, 3 for generating a substantially homogeneous magnetic field (B₀ field) in the examination zone 1 for aligning the nuclear spins of the body tissue of the patient P. It is noted that the magnet 2, 3 may be the ends of a C-shaped magnet or the magnet 2, 3 may be a cylindrical magnet defining a tubular examination zone 1 and substantially enclosing the patient P, as mentioned above. Further, the MR imaging system comprises a RF transmit structure 4 for transmitting RF excitation pulses (B₁ field) for exciting the aligned nuclear spins. A RF receive structure 5 is provided to receive a RF relaxation signal, which is transmitted by the nuclear spins during relaxation after excitation by the RF pulses. The RF transmit structure 4 and the RF receive structure 5 may be the same structure, used for both transmitting and receiving.

In the illustrated embodiment a mobile MR receive (or reception) coil arrangement in the form of an interventional device 6, such as a catheter, for example, is provided with a receive structure for localized RF relaxation signal reception. Such an interventional device 6 is provided with a receive structure in the form of at least one MR receive coil or coil element or coil system in order to enable to track the interventional device 6 by visualization on a display and/or in order to image a small part of the body tissue, e.g. a vascular wall, with a high SNR and with high detail. A transmission line or transfer cable 7 is provided usually as a part of the MR receive coil arrangement to transfer the received signal from the interventional device 6 to an MR receiver (not shown in FIG. 1).

FIG. 2 illustrates the interventional device 6 and its connections in more detail. The interventional device 6 comprises an MR receive coil 9 and a tuning and/or detuning circuit 8. The received MR-signal 12A, 12B is transferred over the transfer cable 7 to an MR receiver 10. In practice, the transfer cable 7 may be partly or totally incorporated in the interventional device 6. In order to prevent signal reception during RF pulse transmission (B₁ field) by the receive coil 9, the tuning and/or detuning circuit 8 is configured to detune the receive structure 8, 9 from the MR frequency (Larmor frequency) in response to a control signal 13A, 13B. The control signal 13A, 13B is generated by a control signal transmitter 11. Both the MR-signal 12A, 12B and the control signal 13A, 13B are transferred over the transfer cable 7.

In accordance with the present invention, the control signal 13A, 13B is an AC control signal. In particular, the transfer cable 7 may be a transformer based transfer cable in order to prevent RF heating of the transfer cable 7 as mentioned above. In such a case, a DC control signal cannot be supplied to the tuning device 8 and an AC (RF) control signal is advantageously employed.

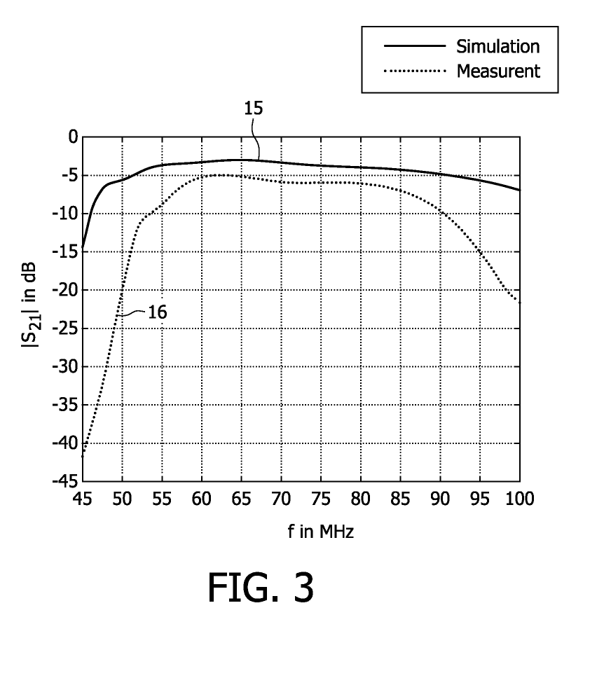

FIG. 3 illustrates a transfer function of an embodiment of a transformer based transfer cable. The horizontal axis represents a signal frequency f (in casu in MHz) and the vertical axis represents a signal attenuation S in dB for a signal transferred through the cable. In FIG. 3, a simulation graph 15 illustrates a transfer function obtained by simulation. A measurement graph 16 illustrates a measured transfer function. From the measured transfer function, i.e. from the measured graph 16, it appears that the cable exhibits a bandwidth of about 30 MHz (from about 55 MHz-about 85 MHz). Commonly, the MR system is employed for imaging hydrogen molecules in a 1.5 T magnetic field having a Larmor frequency of 63.87 MHz. Thus, the transformer based transfer cable 7 is suitable for use in such an MR system, since the MR signal frequency is within the bandwidth of the cable. Moreover, the transformer based transfer cable may be designed to have a minimum attenuation at the MR-signal frequency.

Further, the cable 7 is suitable for transferring any other AC signal within the bandwidth of the cable. For example, an AC control signal to be transferred through the cable may have a frequency above said Larmor frequency of 63.87 MHz and below 85 MHz. In an embodiment, the frequency of an AC control signal is selected such that

$${f}_{c} \neq \frac{1 - n}{m} {f}_{0} \qquad Eq . 1$$

is satisfied, wherein f_{c} is the control frequency, f₀ is the Larmor frequency, n is any integer value, and m is any non-zero integer value. If the condition of Equation 1 is satisfied, any frequency conversion of the AC control signal caused by non-linear elements, such as diodes, for example, will not interfere with the MR-signal and/or the RF pulses at the Larmor frequency. Preferably, for this purpose, the RF control signals are applied at a frequency fc which satisfies the condition |f_{c}−f₀|n≠f₀.

Referring to FIG. 2 again, a two-way branch 14 for coupling the MR receiver 10 and the control signal transmitter 11 to the transfer cable 7 is provided. Such a two-way branch 14 may be constituted by suitable filter circuitry or may be constituted by a circulator, if the control frequency and the MR frequency do not differ by more than about 20%. In an embodiment the control signal transmitter 11 may be constituted by a signal converter connected to the RF pulse generator (B₁ field).

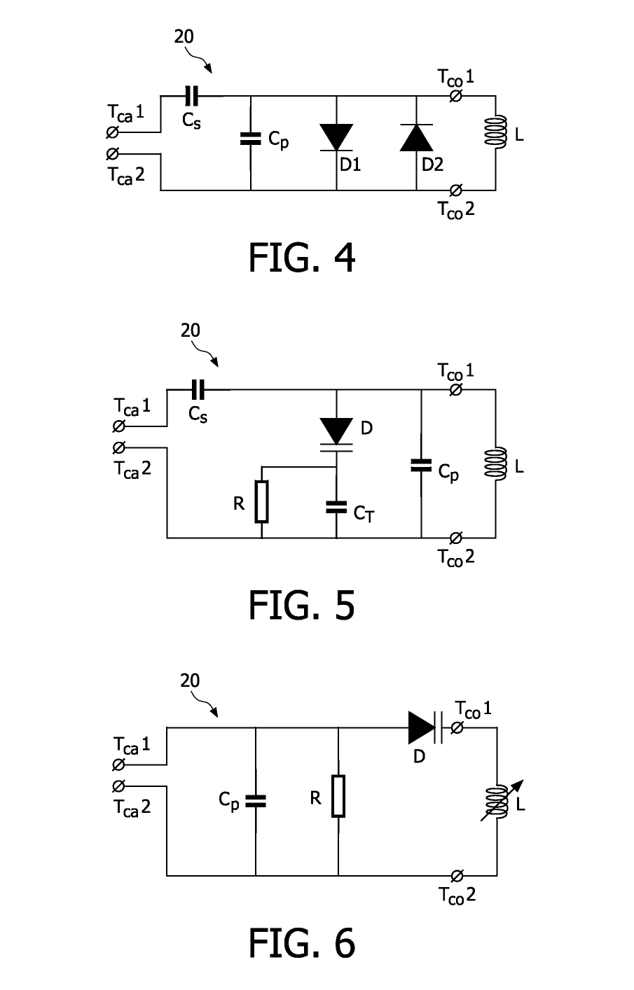

FIG. 4 illustrates a first embodiment of an AC (RF) controllable tuning and/or detuning circuit 20 comprising a first and a second cable terminal Tca1, Tca2, respectively, and a first and a second MR receive coil terminal Tco1, Tco2, respectively. In series with the first and second coil terminals Tco1, Tco2, a series capacitor Cs is connected. In parallel with the first and second coil terminals Tco1, Tco2, a parallel capacitor Cp is connected. In parallel with the parallel capacitor Cp, a first diode D1 and a second diode D2 are connected. The first diode D1 and the second diode D2 are connected anti-parallel. An MR receive coil L is illustrated to be connected to the first and the second coil terminals Tco1, Tco2. It is noted that the second cable terminal Tca2 and the second coil terminal Tco2 may be formed as one terminal.

During MR signal reception by the coil L, the MR signal is transferred to the cable terminals Tca1, Tca2. A suitable cable is connected to the cable terminals Tca1, Tca2 and connected to an MR receiver in order to transfer the MR signal to the MR receiver. Thereto, the capacitance of the series capacitor Cs and the capacitance of the parallel capacitor Cp are selected such that the circuit, including the coil L, is tuned for receiving the MR signal having a frequency equal to the Larmor frequency, e.g. 63.87 MHz (hydrogen; B₀=1.5 T). The first diode D1 and the second diode D2, which may be PIN diodes, will act as capacitances, since the voltages induced by the MR signal reception are so low, that the diodes will not start to conduct. The capacitance of the parallel capacitor Cp is therefore selected taking into account the capacitance of the diodes D1, D2.

When no MR signal is to be received, in particular during RF pulse (B₁ field) generation, an AC/RF control signal is supplied to the cable terminals Tca1, Tca2. The amplitude of the AC/RF control signal is selected such that the diodes D1 and D2 are alternately driven into conduction (forward bias), providing a (very) low impedance, e.g. in the order of 1Ω. Consequently, the parallel capacitor Cp is shorted, thereby detuning the MR reception circuit, i.e. the tuning circuit 20 and the coil L. Thus, no signal is received by the circuit.

In order to save space, one of the diodes D1, D2 may be omitted, although omitting one of the diodes D1, D2 may deteriorate the effectiveness of the detuning method.

FIG. 5 illustrates a second embodiment of an AC controllable tuning circuit 20 comprising a first and a second cable terminal Tca1, Tca2, respectively, and a first and a second coil terminal Tco1, Tco2, respectively. In series with the first and second coil terminals Tco1, Tco2, a series capacitor Cs is connected. In parallel with the first and second coil terminals Tco1, Tco2, a parallel capacitor Cp is connected. In parallel with the parallel capacitor Cp, a varactor diode D is connected. In series with the varactor diode D, a parallel connection of a resistor R and a tuning capacitor C_{T} is connected. A coil L is illustrated to be connected to the first and the second coil terminals Tco1, Tco2. It is noted that the second cable terminal Tca2 and the second coil terminal Tco2 may be formed as one terminal.

The varactor diode D is considered to operate as a diode under a forward bias voltage, i.e. conducting. When a reverse bias voltage is applied to the varactor diode D, however, the varactor diode D functions as a capacitor having a capacitance that decreases with an increasing reverse bias voltage.

When an AC/RF control signal is supplied at the cable terminals Tca1, Tca2, a positive lobe of the AC control signal puts the varactor diode D in forward bias, thereby allowing a current to flow to the tuning capacitor C_{T}. The current will charge the tuning capacitor C_{T}. A negative lobe of the AC/RF control signal will put the varactor D in a reverse bias, thereby preventing that the tuning capacitor C_{T} is discharged. Thus, the varactor diode D effectively operates as a rectifier of the AC/RF control signal for charging the tuning capacitor C_{T}. The charged tuning capacitor C_{T} generates a DC voltage over the varactor diode D via the coil L putting the varactor diode D in reverse bias. The reverse bias voltage over the varactor diode D determines a capacitance of the varactor diode D. For example, an increasing DC voltage generated by charging the tuning capacitor C_{T} decreases the capacitance of the varactor diode D, thereby tuning the reception circuit, i.e. the tuning circuit 20 and the receive coil L, to a higher frequency. When no AC/RF control signal is supplied, the tuning capacitor C_{T} will discharge through the resistor R, the tuning circuit 20 thereby retuning to a base frequency determined by the impedances of the coil L, the parallel capacitor Cp and the series capacitor Cs.

It is noted that the embodiment according to FIG. 5 may be employed to detune the reception circuit, but may as well be employed to tune the reception circuit to the MR frequency. Thereto, an AC/RF control signal may be supplied to the tuning circuit 20 during MR signal reception.

For tuning, the tuning capacitor C_{T} is charged in order to control the capacitance of the varactor diode D as described above. The tuning capacitor C_{T} is charged to a DC voltage

$${U}_{DC} = \frac{{U}_{C , PP}}{2} - {U}_{F} \qquad Eq . 2$$

wherein U_{DC} is the DC voltage over the tuning capacitor C_{T}, U_{C,PP} is the peak-to-peak voltage of the AC control voltage over the varactor diode D, and U_{F} is the forward bias voltage of the varactor diode D. Thus, by controlling the peak-to-peak voltage U_{C,PP} of the AC control signal the tuning frequency of the reception circuit may be controlled.

In an embodiment, the capacitance of the tuning capacitor C_{T} is selected such that the total capacitance of the varactor diode D and the tuning capacitor C_{T} may change significantly. Thereto, the capacitance of the tuning capacitor C_{T} is selected relatively large compared to the capacitance of the varactor diode D. Since the varactor diode D may exhibit a capacitance in the order of 5 pF-100 pF, the capacitance of the tuning capacitor C_{T} may be selected to be 1 nF, for example. It is noted that a large capacitance of the tuning capacitor C_{T} results in a long charging time. Selecting the tuning capacitor C_{T} to have a capacitance of 1 nF results in a charging time in the order of a number of microseconds, assuming a current of about 1 mA and a reverse bias voltage of about 1 V. Thus, the tuning is fast enough for commonly used MR sequences. Selecting the resistor R to have a resistance of about 10 kΩ, the discharging may be performed in about 10 microseconds. Thus, as soon as the AC/RF control signal is switched off, the tuning circuit 20 may tune to its base frequency fast enough for commonly used MR sequences.

In an embodiment, the AC/RF control frequency is selected higher than the MR signal frequency in order to achieve that the amount of control current lost through the coil L is as small as possible. In a further embodiment, the AC control signal may start at a control frequency f_{c} that is nearly equal to the MR frequency. When the resonance frequency of the tuning and/or detuning circuit 20 nearly equals the control frequency f_{c}, the induced resonance may enhance the charging of the tuning capacitor C_{T}. In a further embodiment, the control frequency f_{c} may be gradually increased with the increasing resonance frequency of the tuning and/or detuning circuit 20, thereby substantially optimally making use of the resonance effect. It is noted that in such an embodiment, it may be difficult to satisfy the condition of Equation 1. However, usually the bandwidth of the tuning and/or detuning circuit 20 including the coil L is much larger than the bandwidth used for RF excitation, so that the control frequency f_{c} initially is chosen slightly larger than the MR Larmor frequency, outside the bandwidth used for RF excitation, but still within the bandwidth of the tuning and/or detuning circuit 20 including the coil L.

FIG. 6 illustrates a third embodiment of an AC/RF controllable tuning and/or detuning circuit 20 comprising a first and a second cable terminal Tca1, Tca2, respectively, and a first and a second coil terminal Tco1, Tco2, respectively. In series with the first and second coil terminals Tco1, Tco2, a varactor diode D is connected. In parallel with the varactor diode D and the first and second coil terminals Tco1, Tco2, a parallel capacitor Cp is connected. In parallel with the parallel capacitor Cp, a resistor R is connected. A coil L is illustrated to be connected to the first and the second coil terminals Tco1, Tco2. It is noted that the second cable terminal Tca2 and the second coil terminal Tco2 may be formed as one terminal.

In the third embodiment as illustrated in FIG. 6 the tuning and/or detuning circuit 20 is configured to be tunable during MR signal reception (acquisition) like the second embodiment illustrated in FIG. 5. Such tuning during MR signal reception may advantageously be employed for tuning a flexible coil L, e.g. an expandable coil for intravascular imaging. Upon expansion of an expandable coil, the inductance of the coil changes. The change in inductance results in a change in the resonance frequency of the reception circuit, i.e. the tuning and/or detuning circuit 20 and the coil L, and thus in the tuning frequency. For receiving a signal with high SNR the tuning frequency should be substantially equal to the frequency of the MR signal. Therefore, the reception circuit may be (re)tuned to the MR frequency by supplying a suitable AC control signal to the cable terminals Tca1, Tca2.

To balance a change of inductance of the coil L a capacitor having a variable capacitance is connected in series with the coil L. In the embodiment according to FIG. 6, the capacitor is embodied as a varactor diode D, which acts in reverse bias as a capacitor having a variable capacitance as a function of the reverse bias voltage, as described above. In parallel with the series connection of the coil L and the varactor D the parallel capacitor Cp is connected. In operation, the varactor D acts as a rectifier of an AC/RF control signal, like in the embodiment of FIG. 5, for charging the parallel capacitor Cp. The DC voltage of the charged parallel capacitor Cp puts the varactor diode D in reverse bias and the DC voltage controls the capacitance of the varactor diode D. Thus, as described above, by controlling the amplitude of the AC/RF control signal the capacitance of the varactor diode D may be controlled, thereby tuning the reception circuit. Similarly, the reception circuit may be detuned, i.e. tuned to a frequency significantly different from the MR frequency, in particular the RF pulse (B₁ field) frequency.

The resistor R is provided for discharging the parallel capacitor Cp and the varactor diode D. The parallel capacitor Cp and the varactor diode D may have a total capacitance of about 100 pF. Therefore, the resistor R may have a resistance of about 1 MΩ such that a time constant of about 100 microseconds is achieved for discharging the capacitances. Such a resistor R may be connected in parallel to the coil L without substantially degrading the quality factor of the reception circuit.

Although detailed embodiments of the present invention are disclosed herein, it is to be understood that the disclosed embodiments are merely exemplary of the invention, which can be embodied in various forms. Therefore, specific structural and functional details disclosed herein are not to be interpreted as limiting, but merely as a basis for the claims and as a representative basis for teaching one skilled in the art to variously employ the present invention in virtually any appropriately detailed structure. Further, the mere fact that certain measures are recited in mutually different dependent claims does not indicate that a combination of these measures cannot be used to advantage.

Further, the terms and phrases used herein are not intended to be limiting; but rather, to provide an understandable description of the invention. The terms “a” or “an”, as used herein, are defined as one or more than one. The term another, as used herein, is defined as at least a second or more. The terms including and/or having, as used herein, are defined as comprising (i.e., open language). The term coupled, as used herein, is defined as connected, although not necessarily directly, and not necessarily by means of wires.

1. MR receive coil arrangement which comprises at least one MR receive coil or coil element or coil system (9, L) which can be tuned and/or detuned especially in relation to an MR frequency, and which arrangement further comprises a transmission line (7) for electrically connecting the MR receive coil or coil element or coil system (9, L) with an MR receiver (10), wherein the transmission line (7) is an RF safe transmission line and wherein a tuning and/or detuning circuit (8, 20) is provided which can be controlled for tuning and/or detuning, respectively, the MR receive coil or coil element or coil system (9, L) by means of an RF control signal having a frequency (fc) such that it can be transmitted over the transmission line (7) to the tuning and/or detuning circuit (8, 20).

2. MR receive coil arrangement according to claim 1,
wherein the transmission line (7) is provided for transmitting MR signals which are received by the MR receive coil or coil element or coil system (9, L) to an MR receiver (10).

3. MR receive coil arrangement according to claim 2,
comprising a two-way branch (14) for directing a received MR signal from the transmission line (7) to the MR receiver (10) and for coupling the RF control signal into the transmission line (7).

4. MR receive coil arrangement according to claim 1,
wherein the tuning and/or detuning circuit (8, 20) comprises at least one frequency non-linear electronic element (D; D1, D2) for tuning and/or detuning the MR receive coil or coil element or coil system (9, L) by frequency conversion in dependence on the amplitude of the RF control signal.

5. MR receive coil arrangement according to claim 4,
comprising an RF transmitter unit (11) for generating the RF control signal with selectable amplitudes.

6. MR receive coil arrangement according to claim 1,
wherein the tuning and/or detuning circuit (8, 20) comprises one diode or two anti-parallel diodes (D1, D2), each connected in parallel to the MR receive coil or coil element or coil system (9, L), which is detuned by applying the RF control signal with such an amplitude at the at least one diode (D1, D2) that it is driven into forward bias and having a low impedance, so that the resonance of the MR receive coil or coil element or coil system (9, L) is detuned by short circuiting.

7. MR receive coil arrangement according to claim 1,
wherein the tuning and/or detuning circuit (8, 20) comprises a varactor diode (D) in series with a capacitor (CT), both connected in parallel to the MR receive coil or coil element or coil system (9, L), which is tuned and/or detuned by controlling the capacity of the varactor diode (D) by charging and/or de-charging the capacitor (CT) by accordingly selecting the amplitude of the RF control signal.

8. MR receive coil arrangement according to claim 1,
wherein the tuning and/or detuning circuit (8, 20) comprises a varactor diode (D) which is connected in series with the MR receive coil or coil element or coil system (9, L), and a capacitor (CP) which is connected in parallel with the series connection of the varactor diode (D) and the MR receive coil or coil element or coil system (9, L), which is tuned and/or detuned by controlling the capacity of the varactor diode (D) by charging and/or de-charging the capacitor (CP) by accordingly selecting the amplitude of the RF control signal.

9. MR receive coil arrangement according to claim 1 in the form of an interventional or invasive device, or a surface coil, or a volume coil, or another mobile MR receive coil arrangement.

10. MR imaging or examination system (MRI system) comprising an MR receive coil arrangement according to claim 1.
